(19) United States
(12) Patent Application Publication
(10) Pub. No.: US 2008/0152952 A1
(43) Pub. Date: Jun. 26, 2008

(54) ORGANIC SPIN TRANSPORT DEVICE

(76) Inventors: Tiffany S. Santos, Downers Grove, IL (US); Joo Sang Lee, Seoul (KR); Hyunja Shim, Cambridge, MA (US); Jagadeesh S. Moodera, Somerville, MA (US)

Correspondence Address: GAUTHIER & CONNORS, LLP, 225 FRANKLIN STREET, SUITE 2300, BOSTON, MA, 02110, US

(21) Appl. No.: 11/949,988

(22) Filed: Dec. 4, 2007

Related U.S. Application Data
(60) Provisional application No. 60/869,917, filed on Dec. 14, 2006.

(51) Int. Cl. G11B 5/39; H01L 21/02

(52) U.S. Cl. 428/811.1; 438/3; 438/99; 257/40; 257/E51.024; 257/E21.002

(57) ABSTRACT

The organic spin transport device, such as a magnetic tunnel junction or a transistor, includes at least two ferromagnetic material electrodes. At least one organic semiconductor structure is formed between the at least two ferromagnetic material electrodes. At least one buffer layer is positioned between the at least one organic semiconductor structure and the at least two ferromagnetic material electrodes. The at least one buffer layer reduces spin scattering between the at least two ferromagnetic material electrodes and the at least one organic semiconductor structure. The device exhibits a magnetoresistive effect that depends on the relative magnetization of the two ferromagnetic material electrodes.

### PRIORITY INFORMATION

This application claims priority from provisional application Ser. No. 60/869,917 filed Dec. 14, 2006, which is incorporated herein by reference in its entirety.

### BACKGROUND OF THE INVENTION

The invention relates to the field of magnetoresistive devices, and in particular a magnetoresistive device having a tunnel junction comprising molecular organic semiconductor materials.

There is considerable activity of late in the field of organic electronics both from the fundamental physics point of view as well as with the promise of developing cheaper and flexible devices, such as organic light emitting diodes (OLEDs) and organic transistors. While these materials are exploited for their tunability of charge-carrier transport properties, their spin transport properties is a least explored area, especially for organic semiconductors (OSCs) which are pertinent for future spin-based electronics. Because OSCs are composed of mostly light elements (i.e. C, H, N, O) and thus have a weaker spin-orbit interaction compared to inorganic semiconductors, spin coherence lengths can be long in these materials.

### SUMMARY OF THE INVENTION

According to one aspect of the invention, there is provided a magnetic tunnel junction. The magnetic tunnel junction includes at least two ferromagnetic material electrodes. At least one organic semiconductor structure is formed between the at least two ferromagnetic material electrodes. At least one buffer layer is positioned between the at least one organic semiconductor structure and the at least two ferromagnetic material electrodes. The at least one buffer layer reduces spin scattering between the at least two ferromagnetic material electrodes and the at least one organic semiconductor structure.

According to another aspect of the invention, there is provided a magnetoresistive device. The magnetoresistive device includes at least two ferromagnetic material electrodes. At least one organic semiconductor structure is formed between the at least two ferromagnetic material electrodes. At least one buffer layer is positioned between the at least one organic semiconductor structure and the at least two ferromagnetic material electrodes. The at least one buffer layer reduces spin scattering between the at least two ferromagnetic material electrodes and the at least one organic semiconductor structure.

According to another aspect of the invention, there is provided a method of forming a magnetic tunnel junction. The method includes providing at least two ferromagnetic material electrodes. Also, the method includes forming at least one organic semiconductor structure between the at least two ferromagnetic material electrodes. Furthermore, the method includes forming at least one buffer layer between the at least one organic semiconductor structure and the at least two ferromagnetic material electrodes. The at least one buffer layer reduces spin scattering between the at least two ferromagnetic material electrodes and the at least one organic semiconductor structure.

### BRIEF DESCRIPTION OF THE DRAWINGS

FIG. 1 is a schematic diagram a magnetic tunnel junction (MTJ) formed in accordance with the invention;

FIG. 2 is a graph demonstrating I-V characteristics for a MTJ formed in accordance with the invention;

FIGS. 3A-3B are graphs demonstrating spin polarization measurement of MTJs formed in accordance with the invention;

FIG. 4 is a schematic diagram illustrating a magnetoresistive device formed in accordance with the invention; and

FIG. 5 is a schematic diagram illustrating a transistor structure formed in accordance with the invention.

### DETAILED DESCRIPTION OF THE INVENTION

The invention provides a technique for producing magnetoresistive devices using organic semiconductors materials.

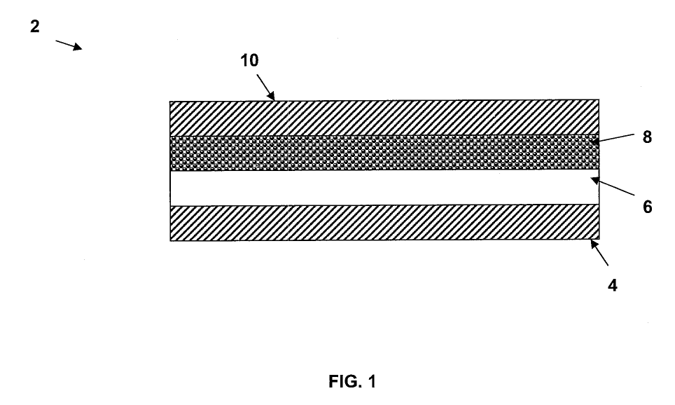

FIG. 1 show a magnetic tunnel junction (MTJ) 2 formed in accordance with the invention. The magnetoresistive tunnel junction 2 includes a first ferromagnetic material layer 4 and a buffer layer 6 is formed on the first ferromagnetic material electrode 4. An organic semiconductor layer 8 is formed on the buffer layer 6. A second ferromagnetic material electrode 10 is formed on the organic semiconductor layer 8.

The first ferromagnetic material electrode 4 and the second ferromagnetic material electrode 10 can include inorganic transition metals such as Co, Fe, or Ni, or alloys of Co, Fe, or Ni, or the half-metallic ferromagnets CrO₂, LaSrMnO₃, or Fe₃O₄. In this embodiment, the first ferromagnetic material electrode 4 includes Co and the second ferromagnetic material electrode 10 includes Ni₈₀Fe₂₀ (Permalloy).

The buffer layer 6 includes materials strategically used to reduce interfacial work function and reduce spin scattering at the interface. Moreover, the buffer layer 6 assists in the growth of a uniform and continuous organic layer and the reduction of charged dipole layers at the interface. In this embodiment, the buffer layer 6 comprises Al₂O₃, however, in other embodiments the buffer layer 6 can include organic or inorganic materials. Also, the buffer layer 6 can include insulating, semiconducting, or metallic materials such as, MgO, LiF, CaO, SiO₂, Si₃N₄, TiO₂, organic polymer, organic molecule, or organic oligomer.

In this embodiment, the organic semiconductor layer 8 includes the organic material Alq₃ (C₂₇H₁₈N₃O₃Al). The organic π-conjugated molecular semiconductor Alq₃, is the most widely used electron transporting and light-emitting material in organic light emitting diodes (OLEDs). Alq₃ has been extensively studied since it displayed high electroluminescence (EL) efficiency nearly two decades ago. A band gap of 2.8 eV separates the highest occupied molecular orbital (HOMO) and the lowest unoccupied molecular orbital (LUMO).

Typically, the film thickness of the Alq₃ layers in OLEDs and structures for MR studies is tens to hundreds of nanometers. In this embodiment, Alq₃ films having <2 nm thick as a tunnel barrier are fabricated. The resistance of this magnetic tunnel junction (MTJ) depends on the relative orientation of the magnetization of the first ferromagnetic material electrode 4 and the second ferromagnetic material electrode 10; lower resistance for parallel alignment (R_{P}) and higher resistance for antiparallel alignment (R_{AP}). Tunnel magnetoresistance (TMR) is defined as ΔR/R=(R_{AP}−R_{P})/R_{P}, and has a positive value for the MTJ 2 with an Alq₃ barrier, even at room temperature.

In other embodiments, the organic semiconductor layer 8 can include organic polymers, oligomers, or molecules. Organic semiconductor layer 8 can be of any thickness—a single molecule, a single molecular layer or several layers. Furthermore, spin transport through the organic layer could be by tunneling or multi-step conduction processes.

The MTJ 2 is prepared in situ in a high vacuum deposition chamber with a base pressure of 6×10⁻⁸ Torr. The MTJ 2 can be deposited on glass substrates at room temperature. The first ferromagnetic material electrode 4 and the second ferromagnetic material electrode 10 are patterned by shadow masks into a cross configuration. The organic semiconductor layer 8 comprising Alq₃ is grown by thermal evaporation from an Alq₃ powder source at a rate of ˜0.3 nm/sec. Junctions with six different Alq₃ thicknesses, from 1 nm to 4 nm, can be prepared in a single run by using a rotating sector disk. A thin Al₂O₃ film of ˜0.6 nm at the interface between the Co electrode and the Alq₃ organic semiconductor layer 8 is formed by depositing Al film and then oxidizing it by a short exposure (˜2 sec) to oxygen plasma. Film thickness was monitored in situ by a quartz crystal oscillator, and the density of Alq₃ used was 1.5 g/cm³.

Growth of the Alq₃ films used to form the organic semiconductor layer 8 is uniform and continuous. X-ray diffraction of the Alq₃ films having thicknesses greater than 50 nm showed the amorphous structure of the film. No change in the chemical structure of Alq₃ is expected during thermal deposition in vacuum, and the monolayer thickness of Alq₃ is ˜1 nm.

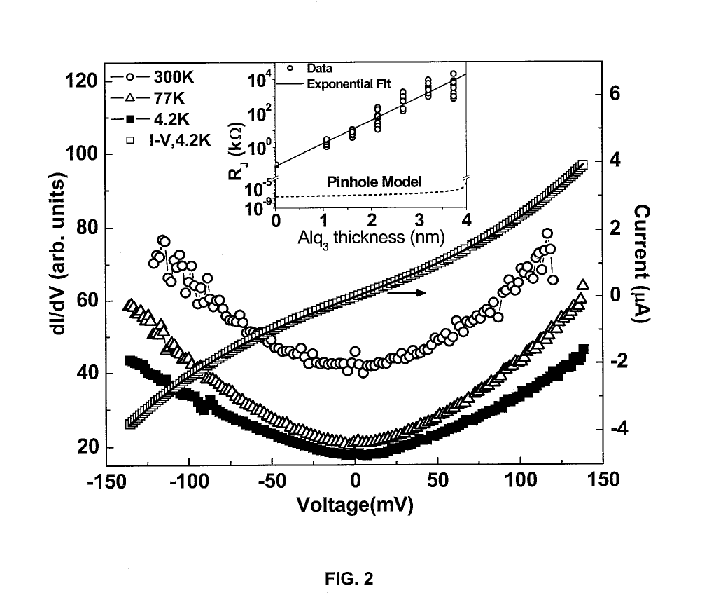

The current-voltage (I-V) characteristics for the MTJ 2 are shown in FIG. 2 are representative of a majority of MTJs measured. The I-V curve yields values of 0.47 eV for tunnel barrier height (Φ), 0.01 eV for barrier asymmetry (ΔΦ), and 3.3 nm for barrier thickness(s). Given an uncertainty in actual barrier thickness used to the form the organic semiconductor layer 8 and the large size of the Alq₃ molecule, a value of s=3.3 nm found from the fit is nominal. The Φ value of 0.47 eV is reasonable for Alq₃ which has a band gap of 2.8 eV.

As shown in FIG. 2, the shape of the conductance (dI/dV) versus bias is similar at room temperature and low temperatures, only shifted down due to the higher R_{J} at lower temperatures. It is necessary to note the absence of a sharp dip at zero bias (known as the zero bias anomaly), especially for lower temperatures. This shows that the barrier and interfaces are free of magnetic inclusions. Presence of such a dip in conductance can be caused by diffusion of magnetic impurities into the barrier, among other possibilities.

In the double barrier structure, with Al₂O₃ and Alq₃, dI/dV versus V at all temperatures is symmetric with no offset present, signifying a rectangular potential barrier. This symmetric barrier is reasonable when considering the low barrier height for ultrathin Al₂O₃ and the amorphous structure of both Al₂O₃ and Alq₃. The junctions are stable up to an applied bias of ±150 mV and show properties that are reproducible over time. These properties—the exponential thickness dependence of R_{J}, strong temperature dependence of R_{J}, and nonlinear I-V, along with the TEM data—confirm that tunneling is occurring through the Alq₃ layer, rather than singly through pinholes and the Al₂O₃ layer. Thus, these organic barrier MTJs show good tunneling behavior.

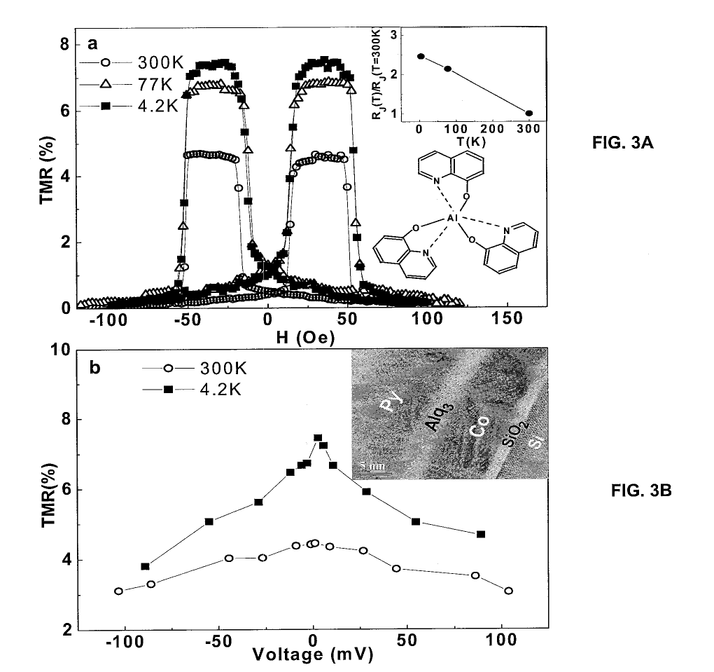

TMR for a 8 nm Co/0.6 nm Al₂O₃/1.6 nm Alq₃/10 nm Py junction, as shown in FIG. 1, measured with a 10 mV bias is shown in FIG. 3A, with TMR values of 4.6, 6.8, and 7.8% at 300, 77, and 4.2 K, respectively. Well-separated coercivities of the Co and Py electrodes yield well-defined parallel and antiparallel magnetization alignment, clearly showing the low resistance (R_{P}) and high resistance (R_{AP}) states, respectively. Similar TMR values and temperature dependence was observed for all Alq₃ barrier junctions. The highest TMR value seen at 300K was 6.0%.

The bias dependence of the TMR for the same junction at 300 K and 4.2 K is shown in FIG. 3B and is symmetric for +V. Substantial TMR persists even beyond 100 mV. Decrease of TMR with increasing bias voltage has been observed for even the best quality MTJs with Al₂O₃ barriers, and is attributed to the excitation of magnons, phonons, band effects, etc. at higher voltages. In addition, for the present junctions with Alq₃ barrier, one can expect chemistry-induced states in the Alq₃ band gap which would give rise to increased temperature and bias dependence as well as reduced.

Given the novel properties discussed above, novel magnetoresistive devices can be formed in accordance with the invention.

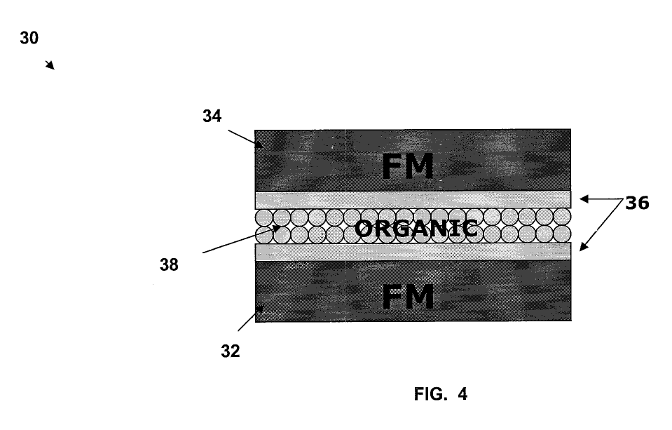

FIG. 4 show a magnetoresistive device 30 formed in accordance with the invention. The magnetoresistive device 30 includes a first ferromagnetic material layer 32 and buffer layers 36 that are formed between the first ferromagnetic material electrode 32, an organic semiconductor layer 38, and a second ferromagnetic material electrode 34.

The first ferromagnetic material electrode 32 and the second ferromagnetic material electrode 34 can include inorganic transition metals such as Co, Fe, LaSrMnO, or alloys such as Co, Fe, or Ni. In this embodiment, the first ferromagnetic material electrode 32 includes Co and the second ferromagnetic material electrode 34 includes Ni₈₀Fe₂₀(Py).

The buffer layers 36 include materials strategically used to reduce interfacial work function and reduce spin scattering at the interface. Moreover, the buffer layers 36 assist in the growth of a uniform and continuous organic layer and the reduction of charged dipole layers at the interface. In this embodiment, the buffer layers 36 comprise Al₂O₃, however, in other embodiments the buffer layer 36 can include organic or inorganic materials. Also, the buffer layers 36 can include insulating, semiconducting, or metallic materials such as, MgO, LiF, SiO₂, CaO, Si₃N₄, TiO₂, organic polymer, organic molecule, or organic oligomer.

In this embodiment, the organic semiconductor layer 38 includes the organic material Alq₃. However, in other embodiment, the organic semiconductor layer 38 can include organic polymers, oligomers, or molecules. Organic semiconductor layer 38 can be of any thickness—a single molecule, a single molecular layer or several layers.

The magnetoresistive device 30 is prepared in situ in a high vacuum deposition chamber. The magnetoresistive device 30 can be deposited on glass substrates at room temperature. The first ferromagnetic material electrode 32 and the second ferromagnetic material electrode 34 are patterned by shadow masks into a cross configuration. The organic semiconductor layer 38 comprising Alq₃ is grown by thermal evaporation from an Alq₃ powder source.

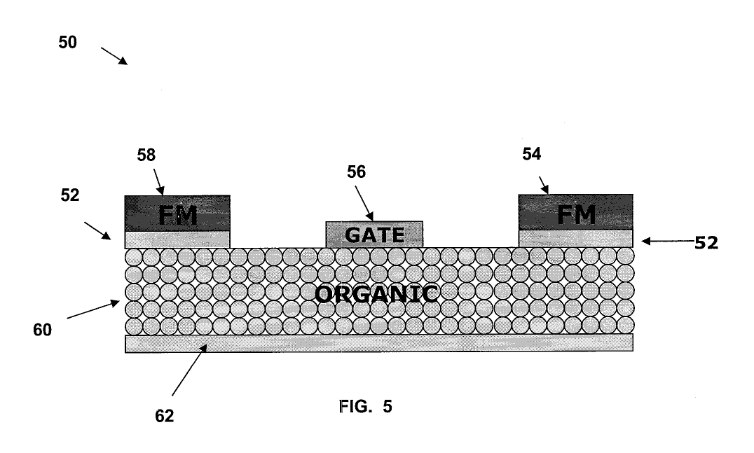

FIG. 5 shows a transistor structure 50 formed in accordance with the invention. The transistor structure 50 includes a first ferromagnetic material electrode 58, a second ferromagnetic material electrode 54 spaced laterally apart from the first ferromagnetic electrode 58, and an organic semiconductor layer 60. The first ferromagnetic material electrode 58 and the second ferromagnetic material electrode 54 can either act as a source or a drain for the transistor structure 50, and they are coupled to the organic semiconductor layer 60 via buffer layers 52. A gate dielectric layer and metallic electrode is also formed on the organic semiconductor layer 60.

Moreover, the first ferromagnetic material electrode 58 and the second ferromagnetic material electrode 54 with their respective buffer layers 52 form multiple MTJs on the organic semiconductor layer 60. Depending on the bias provided to the first ferromagnetic material electrode 58 and the second ferromagnetic material electrode 54, and the gate 56, the output properties of a transistor can be produced. A buffer layer 62 may be formed on the bottom surface of the organic semiconductor layer 60 so as to allow the transistor structure 50 to be deposited on a substrate, such as glass, quartz, plastic, silicon, GaAs, SiO₂ or the like.

The first ferromagnetic material electrode 58 and the second ferromagnetic material electrode 54 can include inorganic transition metals such as Co, Fe, LaSrMnO, or alloys such as Co, Fe, or Ni. In this embodiment, the first ferromagnetic material electrode 4 includes Co and the second ferromagnetic material electrode 10 includes Ni₈₀Fe₂₀ (PY).

The buffer layer 52 and 62 includes materials strategically used to reduce interfacial work function and reduce spin scattering at the interface. Moreover, the buffer layers 52 and 62 assist in the growth of a uniform and continuous organic layer and the reduction of charged dipole layers at the interface. In this embodiment, the buffer layers 52 and 62 comprise Al₂O₃, however, in other embodiments the buffer layers 52 and 62 can include organic or inorganic materials. Also, the buffer layers 52 and 62 can include insulating, semiconducting, or metallic materials such as, MgO, LiF, SiO₂, CaO, Si₃N₄, TiO₂, organic polymer, organic molecule, or organic oligomer.

In this embodiment, the organic semiconductor layer 60 includes the organic material Alq₃. However, in other embodiment, the organic semiconductor layer 60 can include organic polymers, oligomers, or molecules. Organic semiconductor layer 60 can be of any thickness—a single molecule, a single molecular layer or several layers.

Although the present invention has been shown and described with respect to several preferred embodiments thereof, various changes, omissions and additions to the form and detail thereof, may be made therein, without departing from the spirit and scope of the invention.

What is claimed is:

1. A magnetic tunnel junction comprising:
at least two ferromagnetic material electrodes;
at least one organic semiconductor structure formed between said at least two ferromagnetic material electrodes; and
at least one buffer layer positioned between said at least one organic semiconductor structure and said at least two ferromagnetic material electrodes, said at least one buffer layer reduces spin scattering between said at least two ferromagnetic material electrodes and said at least one organic semiconductor structure.

2. The magnetic tunnel junction of claim 1, wherein said at least two ferromagnetic material electrodes comprise a transition metal.

3. The magnetic tunnel junction of claim 1, wherein said at least two ferromagnetic material electrodes comprise metal alloys.

4. The magnetic tunnel junction of claim 2, wherein said ferromagnetic material electrodes comprises Co, Fe, Ni, LaSrMnO₃, CrO₂ or Fe₃O₄.

5. The magnetic tunnel junction of claim 3, wherein said metal alloys comprise alloys of Co, Fe, or Ni.

6. The magnetic tunnel junction of claim 1, wherein said at least one buffer layer comprises insulating, semiconducting, or conducting materials.

7. The magnetic tunnel junction of claim 1, wherein said at least one organic semiconductor structure comprises Alq₃ (C₂₇H₁₈N₃O₃Al), rubrene (C₄₂H₂₈), or pentacene (C₂₂H₁₄).

8. The magnetic tunnel junction of claim 1, wherein said at least one buffer layer comprises include organic polymers, oligomers, or molecules

9. The magnetic tunnel junction of claim 1, wherein said at least one organic semiconductor structure comprises include organic polymers, oligomers, or molecules

10. The magnetic tunnel junction of claim 1, wherein said at least one buffer layer comprises Al₂O₃, MgO, LiF, TiO₂, SiO₂, CaO, or Si₃N₄.

11. A magnetoresistive device comprising:
at least two ferromagnetic material electrodes;
at least one organic semiconductor structure formed between said at least two ferromagnetic material electrodes; and at least one buffer layer positioned between said at least one organic semiconductor structure and said at least two ferromagnetic material electrodes, said at least one buffer layer reduces spin scattering between said at least two ferromagnetic material electrodes and said at least one organic semiconductor structure.

12. The magnetoresistive device of claim 11, wherein said at least two ferromagnetic material electrodes comprise a transition metal.

13. The magnetoresistive device of claim 11, wherein said at least two ferromagnetic material electrodes comprise metal alloys.

14. The magnetoresistive device of claim 12, wherein said ferromagnetic material electrodes comprises Co, Fe, Ni, LaSrMnO₃, CrO₂ or Fe₃O₄.

15. The magnetoresistive device of claim 13, wherein said metal alloys comprise alloys of Co, Fe, or Ni.

16. The magnetoresistive device of claim 11, wherein said at least one buffer layer comprises insulating, semiconducting, or conducting materials.

17. The magnetic tunnel junction of claim 11, wherein said at least one organic semiconductor structure comprises Alq₃ (C₂₇H₁₈N₃O₃Al), rubrene (C₄₂H₂₈), or pentacene (C₂₂H₁₄).

18. The magnetoresistive device of claim 11, wherein said at least one buffer layer comprises include organic polymers, oligomers, or molecules

19. The magnetoresistive device of claim 11, wherein said at least one organic semiconductor structure comprises include organic polymers, oligomers, or molecules

20. The magnetoresistive device of claim 11, wherein said at least one buffer layer comprises Al₂O₃, MgO, LiF, TiO₂, SiO₂, CaO, or Si₃N₄.

21. A method of forming magnetic tunnel junction comprising:
providing at least two ferromagnetic material electrodes;
forming at least one organic semiconductor structure between said at least two ferromagnetic material electrodes; and
forming at least one buffer layer between said at least one organic semiconductor structure and said at two ferromagnetic material electrodes, said at least one buffer layer reduces spin scattering between said at least two ferromagnetic material electrodes and said at least one organic semiconductor structure.

22. The method of claim 11, wherein said at least two ferromagnetic material electrodes comprise a transition metal.

23. The method of claim 11, wherein said at least two ferromagnetic material electrodes comprise metal alloys.

24. The method of claim 12, wherein said ferromagnetic material electrodes comprises Co, Fe, Ni, LaSrMnO₃, CrO₂ or Fe₃O₄.

25. The method of claim 13, wherein said metal alloys comprise alloys of Co, Fe, or Ni.

26. The method of claim 11, wherein said at least one buffer layer comprises insulating, semiconducting, or conducting materials.

27. The method of claim 11, wherein said at least one organic semiconductor structure comprises Alq₃ (C₂₇H₁₈N₃O₃Al), rubrene (C₄₂H₂₈), or pentacene (C₂₂H₁₄).

28. The method of claim 11, wherein said at least one buffer layer comprises include organic polymers, oligomers, or molecules

29. The method of claim 11, wherein said at least one organic semiconductor structure comprises include organic polymers, oligomers, or molecules

30. The method of claim 11, wherein said at least one buffer layer comprises Al₂O₃, MgO, LiF, TiO₂, SiO₂, CaO, or Si₃N₄.
